(19) United States
(12) Patent Application Publication
(10) Pub. No.: US 2025/0309844 A1
(43) Pub. Date: Oct. 2, 2025

(54) AMPLIFIER

(71) Applicant: ABLIC Inc., Nagano (JP)

(72) Inventor: Tomoki HIKICHI, Nagano (JP)

(73) Assignee: ABLIC Inc., Nagano (JP)

(21) Appl. No.: 19/070,493

(22) Filed: Mar. 4, 2025

(30) Foreign Application Priority Data
Mar. 28, 2024 (JP) 2024-053434

(51) Int. Cl. H03F 3/387; H03F 3/45

(52) U.S. Cl. CPC H03F 3/387; H03F 3/45475

(57) ABSTRACT

An amplifier includes: input terminals; chopper circuits capable of switching between a direct connection state and a cross connection state; resistors; a variable resistor; an operational amplifier, including an input port connected to an output port, a control port receiving a control signal, and an input port connected to one end of the resistor and one end of the variable resistor; an operational amplifier, including an input port connected to an output port, a control port receiving a control signal, and an input port connected to one end of the resistor and the other end of the variable resistor; and output terminals. The operational amplifiers are configured to switch their gain bandwidth product based on the control signal.

### CROSS-REFERENCE TO RELATED APPLICATION

This application claims the priority benefit of Japan application serial no. 2024-053434, filed on Mar. 28, 2024. The entirety of the above-mentioned patent application is hereby incorporated by reference herein and made a part of this specification.

### BACKGROUND

### Technical Field

The present invention relates to an amplifier.

### Related Art

A chopper amplifier is used to amplify a minute input voltage, such as, for example, an output signal from a magnetic sensor element, without generating an offset voltage, and to deliver the input voltage to a signal processing circuit in the subsequent stage (for example, see Japanese Patent Laid-Open No. 2012-054766). The chopper amplifier includes a modulator, an amplification stage composed of an operational amplifier, and a demodulator. In the chopper amplifier, after the offset voltage is subjected to frequency conversion into a high frequency domain by the modulator, a signal component is amplified in the amplification stage, and bandwidth limitation is applied to remove the offset voltage modulated into the high frequency domain, and then the signal component is subjected to frequency conversion to be returned to the original frequency by the demodulator.

The modulator and the demodulator are generally composed of chopper switch circuits, and are driven to alternately switch a differential input signal between straight connection and cross connection according to a clock signal of a predetermined frequency so as to output a differential output signal. This predetermined frequency must be sufficiently higher than a frequency bandwidth of an input signal to be amplified in order to output the signal correctly. A closed-loop gain of the amplification stage is set using a ratio of feedback resistances or the like. Considering a dynamic range of a sensor in the preceding stage or the like, the closed-loop gain is preset in an inspection process at the time of shipment, or is dynamically automatically controlled to be switched and set.

However, in the amplifier of the related art, a bandwidth BW of the operational amplifier constituting the chopper amplifier may vary depending on the closed-loop gain setting of the entire chopper amplifier, an effective chopper amplifier gain reduction rate according to insufficient settling time may vary depending on the closed-loop gain setting, the effective chopper amplifier gain may become unstable with respect to the gain setting, and convenience is poor.

A reason thereof is described. The operational amplifier has a gain bandwidth product GBW determined by a drive current and a compensation capacitance value. The gain bandwidth product GBW can be expressed as follows using closed-loop gain G and bandwidth BW:

$$GBW = G \cdot BW \qquad ( 1 )$$

A time constant t that determines a settling time of an output signal from the amplification stage with respect to a final value, in which the amplification stage amplifies an output signal from a chopper switch driven at a predetermined clock frequency, is limited by the bandwidth BW, and can be expressed as follows:

$$τ \approx 0.35 / BW [ μs ] \qquad ( 2 )$$

In the case where it is not ensured that a time of one half of a clock corresponding to the predetermined clock frequency is sufficiently long with respect to the time constant t, a settling error may occur, and the effective chopper amplifier gain may be reduced. On the other hand, as mentioned above, when an attempt is made to achieve a high-speed response corresponding to a wide frequency bandwidth of the input signal, a relatively high frequency is set for the predetermined clock frequency. Here, the gain bandwidth product GBW of a general operational amplifier can be expressed as follows using transconductance Gm of the operational amplifier, current value IDD of the drive current, and capacitance value Cc of phase compensation capacitance:

$$GBW ∝ Gm / Cc = √ IDD / Cc \qquad ( 3 )$$

That is, the gain bandwidth product GBW is proportional to the square root (½ power) of the current value IDD of the drive current and inversely proportional to the capacitance value Cc of the phase compensation capacitance.

To increase the gain bandwidth product GBW of the operational amplifier, as can be seen from equation (3), it is sufficient to either increase the current value IDD of the drive current or decrease the capacitance value Cc of the phase compensation capacitance, or both increase the current value IDD of the drive current and decrease the capacitance value Cc of the phase compensation capacitance. However, when the current value IDD of the drive current is increased, power consumption of the amplifier may be prevented from being reduced. When the phase compensation capacitance is decreased or eliminated, insufficient phase margin of a negative feedback system may be caused. When the negative feedback system has insufficient phase margin, ringing may occur in a waveform of an output voltage, which can be a factor contributing to an error in equivalent gain of the chopper amplifier.

### SUMMARY

The present invention provides an amplifier in which a stable effective chopper amplifier gain can be obtained with respect to closed-loop gain setting of an amplification stage.

In accordance with an embodiment of the present invention, an amplifier includes: a first input terminal and a second input terminal; a first chopper circuit, including a first input port connected to the first input terminal, a second input port connected to the second input terminal, a control port receiving a clock signal as a switching signal, a first output port, and a second output port, the first chopper circuit being capable of switching, based on the switching signal, between a first connection state in which the first input port is connected to the first output port and the second input port is connected to the second output port, and a second connection state in which the first input port is connected to the second output port and the second input port is connected to the first output port; a first resistor; a second resistor, including at least one control port and capable of switching a resistance value based on a control signal applied to the control port; a third resistor; a first operational amplifier, including a first input port connected to the first output port of the first chopper circuit, a second input port connected to one end of the first resistor and one end of the second resistor, an output port connected to the other end of the first resistor, and a control port receiving the control signal; a second operational amplifier, including a first input port connected to the second output port of the first chopper circuit, a second input port connected to one end of the third resistor and the other end of the second resistor, an output port connected to the other end of the third resistor, and a control port receiving the control signal; a second chopper circuit, including a first input port connected to the output port of the first operational amplifier, a second input port connected to the output port of the second operational amplifier, a control port receiving the clock signal as the switching signal, a first output port, and a second output port, the second chopper circuit being capable of switching, based on the switching signal, between a first connection state in which the first input port is connected to the first output port and the second input port is connected to the second output port, and a second connection state in which the first input port is connected to the second output port and the second input port is connected to the first output port; and a first output terminal connected to the first output port of the second chopper circuit and a second output terminal connected to the second output port of the second chopper circuit. The first operational amplifier and the second operational amplifier are configured to switch a gain bandwidth product of the first operational amplifier and the second operational amplifier based on the control signal.

According to an embodiment of the present invention, a stable effective chopper amplifier gain can be obtained with respect to closed-loop gain setting of an amplification stage.

### BRIEF DESCRIPTION OF THE DRAWINGS

FIG. 1 is a circuit diagram schematically illustrating a configuration of an amplifier according to a first embodiment of the present invention.

FIG. 2 is a circuit diagram illustrating a configuration example of a chopper circuit in the amplifier according to the present embodiment.

FIG. 3 is a circuit diagram illustrating a configuration example of a variable resistor in the amplifier according to the present embodiment.

FIG. 4 is a circuit diagram illustrating a configuration example of an operational amplifier in the amplifier according to the first embodiment.

FIG. 5 is a circuit diagram illustrating a configuration example of a capacitor bank circuit in the amplifier according to the first embodiment.

FIG. 6 is a timing diagram illustrating temporal changes in a clock signal and input signal supplied to the amplifier according to the present embodiment and a conventional amplifier (Comparative Example), as well as a modulator output signal (modulated input signal).

FIG. 7 is a timing diagram of an operation of the amplifier according to the present embodiment and the conventional amplifier (Comparative Example).

FIG. 8A and FIG. 8B illustrate frequency characteristics of closed-loop gain with respect to a closed-loop gain design in an amplifier of the related art and the amplifier according to the present embodiment, respectively. FIG. 8C and FIG. 8D respectively illustrate effective gain and normalized effective gain (=effective gain/set gain) by an ideal straight line of a chopper amplifier with respect to set gain.

FIG. 9 is a circuit diagram schematically illustrating a configuration of an amplifier according to a second embodiment of the present invention.

FIG. 10 is a circuit diagram illustrating a configuration example of an operational amplifier in the amplifier according to the second embodiment.

FIG. 11 is a circuit diagram illustrating a configuration example of a variable current source circuit in the amplifier according to the second embodiment.

### DESCRIPTION OF THE EMBODIMENTS

An amplifier according to embodiments of the present invention will be described below based on the drawings. For the ease of description, some components may be omitted from illustration or scales may be changed.

### First Embodiment

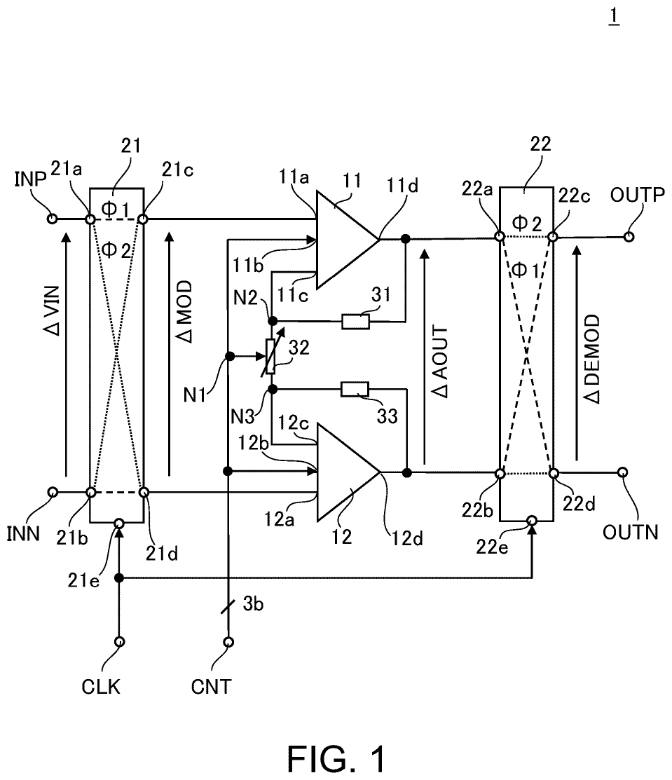

FIG. 1 is a circuit diagram schematically illustrating a configuration of an amplifier 1 which is an example of an amplifier according to a first embodiment of the present invention.

The amplifier 1 includes input terminals INP and INN, a chopper circuit 21, operational amplifiers 11 and 12, resistors 31 and 33, a variable resistor 32, a chopper circuit 22, a clock terminal CLK which receives a clock signal, a control terminal CNT which receives a 3-bit (3b) control signal, and output terminals OUTP and OUTN.

The chopper circuit 21 includes an input port 21a connected to the input terminal INP, an input terminal 21b connected to the input terminal INN, output ports 21c and 21d, and a control port 21e connected to the clock terminal CLK. The chopper circuit 21 is configured to be capable of switching a connection state between a period of phase Φ1 and a period of phase Φ2 of the clock signal received from the clock terminal CLK. The chopper circuit 21 is in a direct connection state (dashed line) during the period of phase Φ1 of the clock signal, and is in a cross connection state (dotted line) during the period of phase Φ2.

The operational amplifier 11 includes an input port 11a connected to the output port 21c, a control port 11b connected to node N1 where the control signal is supplied, an input port 11c connected to node N2 which is a connection point between the resistor 31 and the variable resistor 32, and an output port 11d connected to the input port 11c via the resistor 31. The operational amplifier 12 includes an input port 12a connected to the output port 21d, a control port 12b connected to node N1, an input port 12c connected to node N3 which is a connection point between the variable resistor 32 and the resistor 33, and an output port 12d connected to the input port 12c via the resistor 33. The variable resistor 32 includes a first port connected to node N2, a second port connected to node N3, and a control port which receives the control signal, and is configured to be capable of adjusting a resistance value between the first port and the second port based on the control signal.

The chopper circuit 22 includes an input port 22a connected to the operational amplifier 11 (specifically, the output port 11d), an input port 22b connected to the operational amplifier 12 (specifically, the output port 12d), an output port 22c connected to the output terminal OUTP, an output port 22d connected to the output terminal OUTN, and a control port 22e connected to the clock terminal CLK. Similarly to the chopper circuit 21, the chopper circuit 22 is configured to be capable of switching a connection state between the period of phase Φ1 and the period of phase Φ2 of the clock signal. The chopper circuit 22 is in the cross connection state (dashed line) during the period of phase Φ1 of the clock signal, and in the direct connection state (dotted line) during the period of phase Φ2.

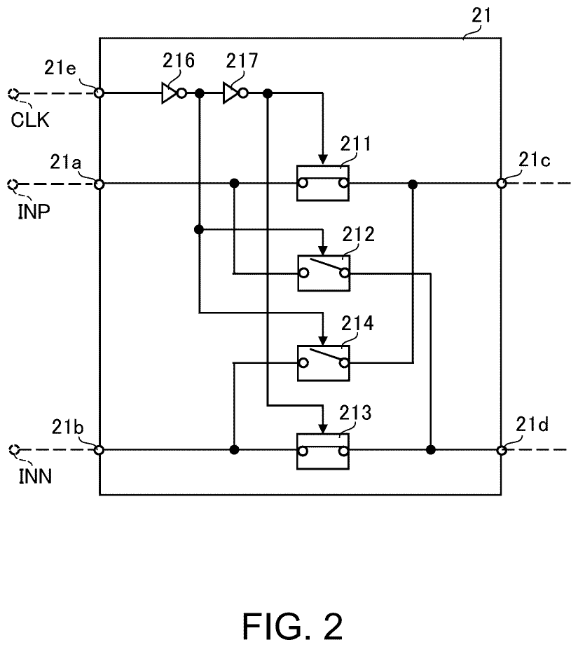

FIG. 2 is a circuit diagram illustrating a configuration example of the chopper circuit 21.

In addition to including the input terminals 21a, 21b, the output ports 21c, 21d, and the control port 21e, the chopper circuit 21 includes switches 211 to 214 each including a control port, an inverter 216 including an input port and an output port connected to the control port 21e, and an inverter 217 including an input port and an output port connected to the output port of the inverter 216.

The switch 211 is connected between the input port 21a and the output port 21c, capable of opening and closing connection between the input port 21a and the output port 21c. The switch 212 is connected between the input port 21a and the output port 21d, capable of opening and closing connection between the input port 21a and the output port 21d. The switch 213 is connected between the input port 21b and the output port 21d, capable of opening and closing connection between the input port 21b and the output port 21d. The switch 214 is connected between the input port 21b and the output port 21c, capable of opening and closing connection between the input port 21b and the output port 21c. The control ports of the switch 211 and the switch 214 are, for example, connected to the output port of the inverter 217. The control ports of the switch 212 and the switch 213 are connected to the output port of the inverter 216.

Accordingly, the switches 211 and 213 are configured to be in an open state (off state) with both ends open in the case where the switches 212 and 214 are in a closed state (on state) with both ends short-circuited, and to be in the closed state (on state) in the case where the switches 212 and 214 are in the open state (off state). That is, the switches 211, 213 and the switches 212, 214 are configured to have mutually exclusive open-closed states.

The configuration of the chopper circuit 22 does not substantially differ from the configuration of the chopper circuit 21. Thus, the description of the chopper circuit 21 may be substituted for the description of the chopper circuit 22 by replacing the reference numerals in the description of the chopper circuit 21.

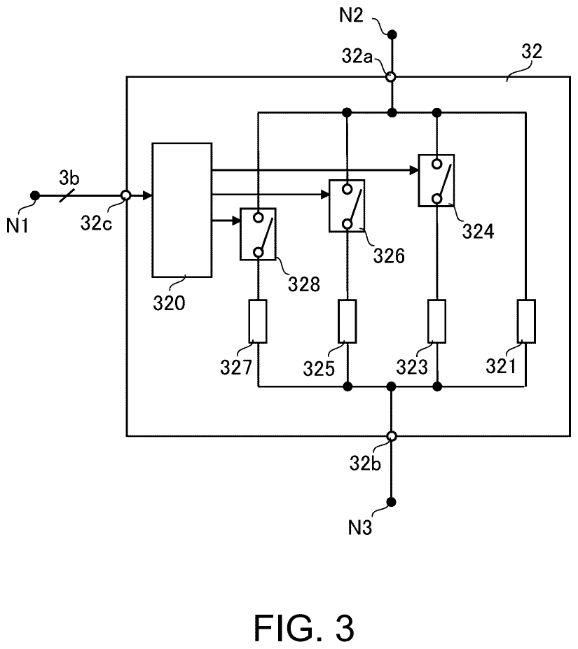

FIG. 3 is a circuit diagram illustrating a configuration example of the variable resistor 32.

In addition to including a first port 32a, a second port 32b, and a control port 32c, the variable resistor 32 includes a decoder circuit 320, resistive elements 321, 323, 325, 327, and switch circuits 324, 326, 328 each including a control port. The decoder circuit 320 includes an input port connected to the control port 32c, and an output port that outputs a signal after decoding the control signal received from the input port.

The resistive element 321, the resistive element 323 and the switch circuit 324 connected in series, the resistive element 325 and the switch circuit 326 connected in series, and the resistive element 327 and the switch circuit 328 connected in series, are respectively connected in parallel between the first port 32a and the second port 32b. The control port of each of the switch circuits 324, 326, and 328 is connected to each output port of the decoder circuit 320. The variable resistor 32 is configured to adjust a resistance value between the first port 32a and the second port 32b in a stepwise manner within a predetermined range by controlling the open-closed state of the switch circuits 324, 326, and 328.

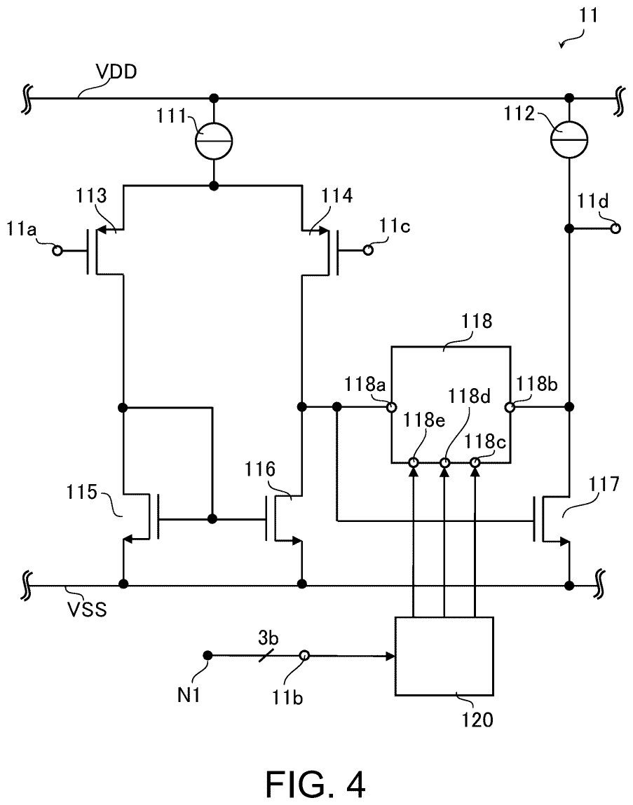

FIG. 4 is a circuit diagram illustrating a first configuration example of the operational amplifier 11.

In addition to including the input ports 11a, 11c, the control port 11b, and the output port 11d, the operational amplifier 11 includes a current source 111, a current source 112, a PMOS transistor 113, a PMOS transistor 114, an NMOS transistor 115, an NMOS transistor 116, an NMOS transistor 117, a capacitor bank circuit 118, and a decoder circuit 120.

The current source 111 includes a first port connected to a power line VDD (power supply terminals are omitted from illustration) that supplies a power supply voltage Vdd, and a second port. The current source 112 includes a first port connected to the power line VDD that supplies the power supply voltage Vdd, and a second port connected to the output port 11d. The source of the PMOS transistor 113 and the source of the PMOS transistor 114 are each connected to the second port of the current source 111. The gate of the PMOS transistor 113 is connected to the input port 11a. The gate of the PMOS transistor 114 is connected to the input port 11c.

The drain of the PMOS transistor 113 is connected to the drain and gate of the NMOS transistor 115 and the gate of the NMOS transistor 116. The source of the NMOS transistor 115 and the source of the NMOS transistor 116 are each connected to a power line VSS (power supply terminals are omitted from illustration) that supplies a power supply voltage Vss (≠Vdd). The drain of the NMOS transistor 116 is connected to the drain of the PMOS transistor 114. The NMOS transistor 117 includes the gate connected to the drain of the PMOS transistor 114 and the drain of the NMOS transistor 116, the drain connected to the second port of the current source 112, and the source connected to the power line VSS.

The capacitor bank circuit 118 includes: a first port 118a, connected to the drain of the PMOS transistor 114, the drain of the NMOS transistor 116, and the gate of the NMOS transistor 117; a second port 118b, connected to the drain of the NMOS transistor 117, the output port 11d, and the second port of the current source 112; and three control ports 118c, 118d, 118e respectively connected to three output ports of the decoder circuit 120. The decoder circuit 120 includes an input port connected to the control port 11b, and three output ports that respectively output signals after decoding the control signal received from the input port.

The configuration of the operational amplifier 12 is substantially the same as that of the operational amplifier 11. Thus, the description of the operational amplifier 11 may be substituted for the description of the operational amplifier 12 by replacing the reference numerals in the description of the operational amplifier 11.

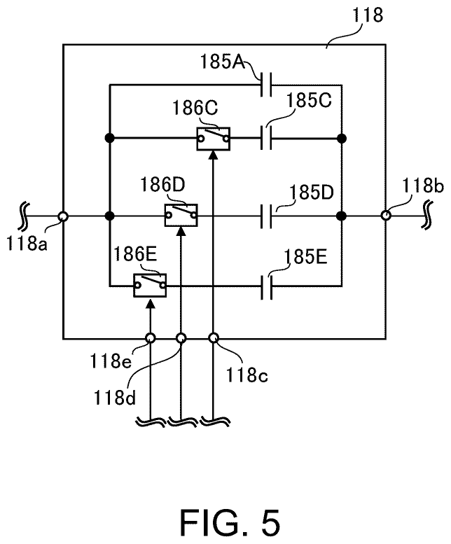

FIG. 5 is a circuit diagram illustrating a configuration example of the capacitor bank circuit 118.

In addition to including the first port 118a, the second port 118b, and three control ports 118c, 118d, and 118e, the capacitor bank circuit 118 includes capacitive elements 185A, 185C, 185D, 185E, and switches 186C, 186D, 186E. The capacitive element 185A, the capacitive element 185C and the switch 186C connected in series, the capacitive element 185D and the switch 186D connected in series, and the capacitive element 185E and the switch 186E connected in series, are respectively connected in parallel between the first port 118a and the second port 118b.

Control ports of the switches 186C, 186D, and 186E are connected to the control ports 118c, 118d, and 118e, respectively. The capacitor bank circuit 118 is configured to adjust a capacitance value between the first port 118a and the second port 118b in a stepwise manner within a predetermined range by controlling the open-closed state of the switches 186C, 186D, and 186E.

Next, a function of the amplifier according to an embodiment of the present invention will be described using the amplifier 1 as an example. An amplification stage which includes the operational amplifier 11, the operational amplifier 12, the resistor 31, the variable resistor 32, and the resistor 33 has a configuration of a so-called instrumentation amplifier. Thus, by switching a resistance value of the variable resistor 32, closed-loop gain of the amplification stage can be switched. Here, it is assumed that the control signal supplied from the control terminal CNT is, for example, 3 bits, and minimum closed-loop gain G8 is set in the case of 0b000, while maximum closed-loop gain G1 is set in the case of 0b111.

If the resistance values of the resistor 31, the resistor 33, the resistive element 321, the resistive element 323, the resistive element 325, and the resistive element 327 of the variable resistor 32 are set as a resistance value R1, a resistance value R3, a resistance value R21, a resistance value R22, a resistance value R23, and a resistance value R24, respectively, when the switch circuits 324, 326, and 328 have a sufficiently small on-resistance value, the maximum closed-loop gain G1 and the minimum closed-loop gain G8 can be respectively expressed as follows:

$$\begin{matrix}G ( G 1 ) = ( R 1 + R 3 ) \cdot ( 1 / R 21 ) \\ = ( R 1 + R 3 ) \cdot G 21\end{matrix} \qquad ( 4 )$$

$$\begin{matrix}G ( G 8 ) = ( R 1 + R 3 ) \cdot ( 1 / R 21 + 1 / R 22 + 1 / R 23 + 1 / R 24 ) \\ = ( R 1 + R 3 ) \cdot \sum G 2 x\end{matrix} \qquad ( 5 )$$

Here, G2x is the reciprocal of R2x (=1/R2x), and x represents any arbitrary subscript (in this example, x is any of 1, 2, 3, or 4). Each ratio between resistance values are selected so that a gain range required according to a dynamic range of an input signal required for the amplifier 1 can be comprehensively set.

The capacitor bank circuit 118 is a so-called Miller compensation capacitor. Thus, by switching a capacitance value of the capacitor bank circuit 118, a gain bandwidth of the operational amplifier 11 and the operational amplifier 12 can be switched. Here, it is assumed that the control signal supplied from the control terminal CNT is, for example, 3 bits. The capacitance value is set to (C0+C1+C2+C3) in the case of 0b000, namely in the case of the minimum closed-loop gain G8, and the capacitance value is set to C0 in the case of 0b111, namely in the case of the maximum closed-loop gain G1.

When the transconductance of the operational amplifiers 11 and 12 is Gm, the gain bandwidth product GBW(G1) corresponding to the maximum closed-loop gain G1 and the gain bandwidth product GBW(G8) corresponding to the minimum closed-loop gain G8 can be respectively expressed as follows:

$$\begin{matrix}GBW ( G 1 ) = G ( G 1 ) \cdot BW ( G 1 ) \\ = Gm / C 0\end{matrix} \qquad ( 6 )$$

$$\begin{matrix}GBW ( G 8 ) = G ( G 8 ) \cdot BW ( G 8 ) \\ = Gm / ( C 0 + C 1 + C 2 + C 3 )\end{matrix} \qquad ( 7 )$$

Here, according to the relationships in equations (4) to (7), it is sufficient to satisfy a relationship BW(G1)=BW(G8) in order to obtain equal bandwidth BW for the maximum closed-loop gain G1 and the minimum closed-loop gain G8. That is, it is sufficient to determine a constant so as to satisfy the following equation (8):

$$G 21 / \sum G 2 x = C 0 / \sum Cx \qquad ( 8 )$$

For intermediate closed-loop gain setting, it is sufficient to determine a constant so as to satisfy similar relationships.

Next, functions and effects of the amplifier according to the present embodiment will be described in comparison with an operation of a conventional amplifier (Comparative Example).

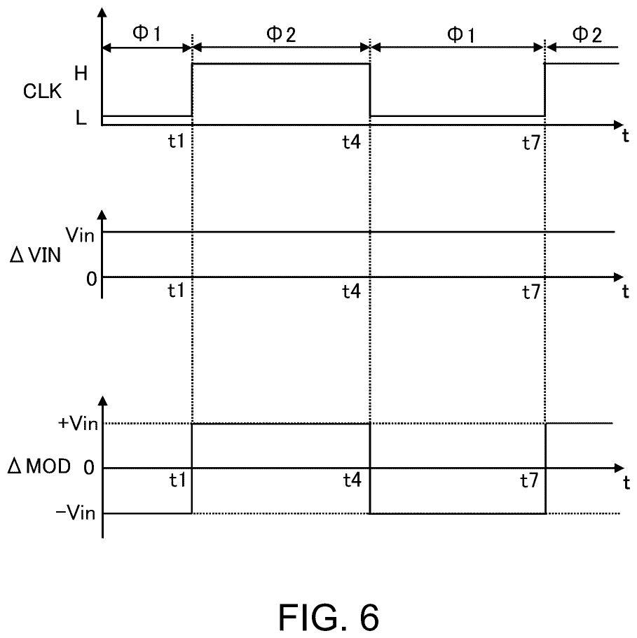

FIG. 6 is a timing diagram illustrating temporal changes in a clock signal and input signal supplied to the amplifier 1 and the conventional amplifier (Comparative Example), as well as a modulator output signal (modulated input signal). FIG. 6 includes three different timing diagrams, which are, from top to bottom, the clock signal (CLK), an input differential signal ΔVIN, and a modulator output signal ΔMOD.

The clock signal supplied from the clock terminal CLK is a binary clock signal which periodically alternates between a first state “L” and a second state “H”, transitioning from “L” to “H” at time t1 and from “H” to “L” at time t4. For example, in the case of CLK=“L”, that is, during the period of phase Φ1, the chopper circuit 21 functioning as a modulator and the chopper circuit 22 functioning as a demodulator may be switched to the direct connection state and the cross connection state, respectively. In the case of CLK=″H″, that is, during the period of phase Φ2, the chopper circuit 21 and the chopper circuit 22 may be switched to the other connection states, namely the cross connection state and the direct connection state, respectively, in contrast to the connection states in the case of CLK=″L″. Here, to simplify the description, the input differential signal ΔVIN, which is a differential voltage received by the input terminals INP and INN, is assumed to be a positive constant value “Vin”, and an offset voltage is assumed to be zero in the illustration.

The modulator output signal ΔMOD, which is an output signal from the chopper circuit 21, is a modulated signal obtained by modulating the input differential signal ΔVIN in synchronization with the clock signal using the chopper circuit 21. The response of the modulator output signal ΔMOD is predominantly determined by the on-resistance of a conductive state of the chopper circuit 21 and a time constant based on an input capacitance of the operational amplifiers 11 and 12, and is generally sufficiently fast. Thus, the modulator output signal ΔMOD is illustrated as a rectangular wave in FIG. 6.

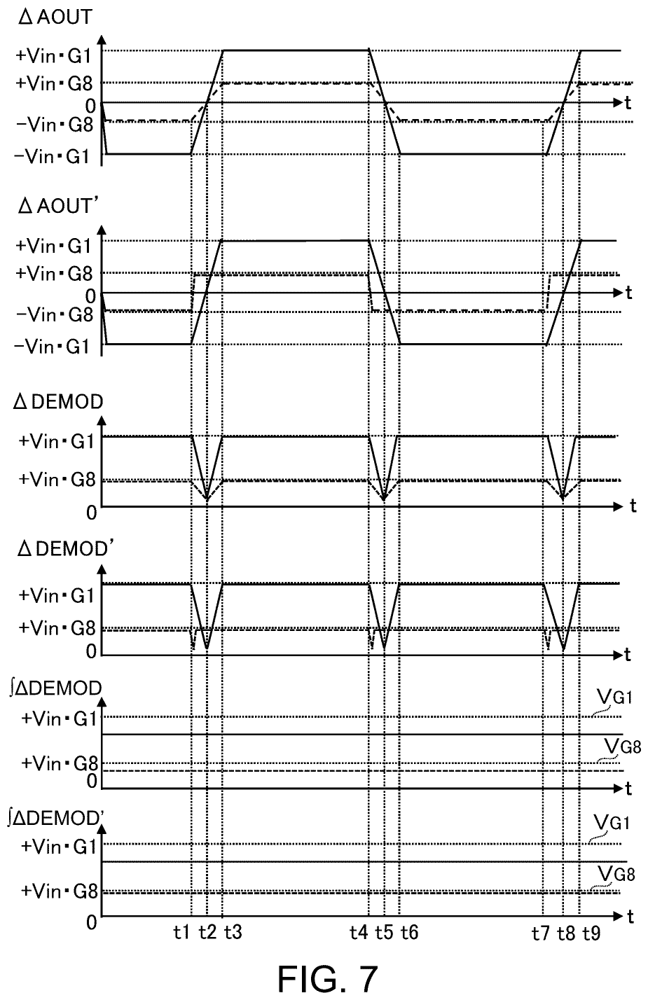

FIG. 7 is a timing diagram of an operation of the amplifier 1 and the conventional amplifier (Comparative Example). FIG. 7 includes six timing charts respectively representing response waveforms of, from top to bottom, amplification stage output signal ΔAOUT of the present embodiment, amplification stage output signal ΔAOUT′ of the related art, demodulator output signal ΔDEMOD of the present embodiment, demodulator output signal ΔDEMOD′ of the related art, integrated value ∫ΔDEMOD obtained by smoothing the demodulator output signal ΔDEMOD of the present embodiment, and integrated value ∫ΔDEMOD′ obtained by smoothing the demodulator output signal ΔDEMOD′ of the related art, with respect to time. The maximum closed-loop gain G1 is illustrated as a solid line, and the minimum closed-loop gain G8 is illustrated as a dashed line. From time t7 onward, the description is omitted as it is a repetition of that of time t1 to time t6.

The amplification stage output signal ΔAOUT, which is an output signal from the amplification stage in the amplifier 1, is a differential signal between the output port 11d of the operational amplifier 11 and the output port 12d of the operational amplifier 12. Since the amplification stage output signal ΔAOUT has finite response, if any closed-loop gain from the maximum closed-loop gain G1 to the minimum closed-loop gain G8 is set as Gn (where n is a natural number from 1 to 8), the closed-loop gain settles from an initial value of −Vin·Gn to a final value of +Vin·Gn during a period from time t1 to time t3, and settles from an initial value of +Vin·Gn to a final value of −Vin·Gn during a period from time t4 to time t6. Here, the response waveforms when set to the maximum closed-loop gain G1 or the minimum closed-loop gain G8 are similar since the bandwidths BW are equal.

On the other hand, since the amplification stage output signal ΔAOUT′ of the related art has finite response, the closed-loop gain Gn similarly settles from the initial value of −Vin·Gn to the final value of +Vin·Gn during the period from time t1 to t3, and settles from the initial value of +Vin·Gn to the final value of −Vin·Gn during the period from time t4 to t6. However, the response waveforms when set to the maximum closed-loop gain G1 or the minimum closed-loop gain G8 are not similar since the bandwidths BW are not equal.

As mentioned above, the amplification stage output signal ΔAOUT has similar waveforms when set to the maximum closed-loop gain G1 and the minimum closed-loop gain G8, respectively. Thus, the demodulator output signal ΔDEMOD, which is an output signal from the chopper circuit 22 functioning as the demodulator in the amplifier 1, has similar demodulation waveforms.

On the other hand, the amplification stage output signal ΔAOUT′ does not have similar waveforms when set to the maximum closed-loop gain G1 and the minimum closed-loop gain G8, respectively. Thus, the demodulator output signal ΔDEMOD′ of the related art does not have similar demodulation waveforms.

As mentioned above, the demodulator output signal ΔDEMOD has similar waveforms when set to the maximum closed-loop gain G1 and the minimum closed-loop gain G8, respectively. Thus, the integrated value ∫ΔDEMOD in the amplifier 1 has similar integrated values, and has equal attenuation rates with respect to an ideal value VG1 (=Vin·G1) and an ideal value VG8 (=Vin·G8). Hence, it becomes easy to obtain a stable chopper amplifier gain with respect to the set closed-loop gain.

On the other hand, as mentioned above, the demodulator output signal ΔDEMOD′ does not have similar waveforms when set to the maximum closed-loop gain G1 and the minimum closed-loop gain G8, respectively. Thus, the integrated value ∫ΔDEMOD′ of the related art does not have similar integrated values, and has different attenuation rates with respect to the ideal value VG1 (=Vin·G1) and the ideal value VG8 (=Vin·G8). Hence, it becomes difficult to obtain a stable chopper amplifier gain with respect to the set closed-loop gain.

In this manner, according to the amplifier of the present embodiment, in comparison with the related art, a stable effective chopper amplifier gain can be obtained with respect to the closed-loop gain setting of the amplification stage.

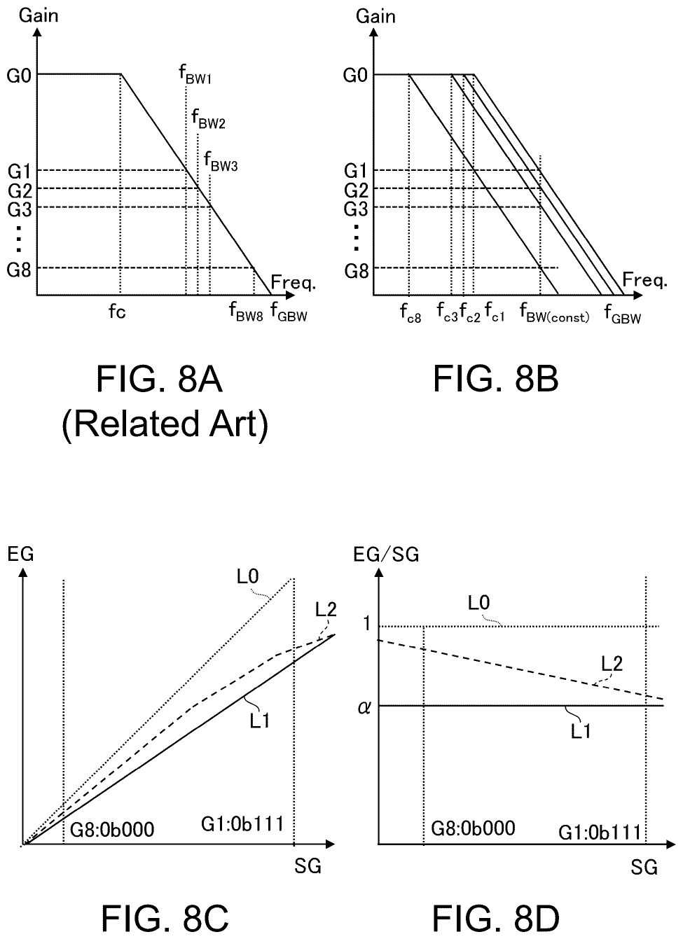

FIG. 8A to FIG. 8D respectively illustrate, frequency characteristics of closed-loop gain with respect to closed-loop gain designs G1 to G8 in the amplifier of the related art, frequency characteristics of closed-loop gain with respect to closed-loop gain designs (from the maximum closed-loop gain G1 to the minimum closed-loop gain G8) of the amplifier 1, a relationship diagram representing effective gain with respect to set gain, and a relationship diagram representing normalized effective gain (=effective gain/set gain) by an ideal straight line of a chopper amplifier with respect to set gain.

First, FIG. 8A will be described. Here, G0 illustrated in FIG. 8A indicates an open-loop gain curve indicating open-loop gain of an operational amplifier, G1 to G8 indicate DC closed-loop gains at the maximum set gain to the minimum set gain, fc indicates cutoff frequency of the operational amplifier, f_{GBW} indicates gain bandwidth of the operational amplifier, and f_{BW1} to f_{BW8} indicate bandwidths at the maximum set gain to the minimum set gain. According to FIG. 8A, the bandwidths f_{BW1} to f_{BW8} at each set gain are determined by the open-loop gain curve G0 of the operational amplifier and intersections of each set gain G1 to G8 and the DC closed-loop gain. Thus, the bandwidths f_{BW1} to f_{BW8} at each set gain decrease as the set gain increases, and increase as the set gain decreases. Thus, if the set gain is high, the response of the amplification stage is poor; if the set gain is low, the response of the amplification stage is good. Accordingly, the response of the amplification stage may change depending on the set gain, resulting in a change in deviation in equivalent gain of the chopper amplifier from a design value.

Next, FIG. 8B will be described. Here, f_{c1} to f_{c8} at the maximum set gain to the minimum set gain indicate cutoff frequencies of the operational amplifier, and f_{BW(const)} indicates a bandwidth common to all set gains. G0 to G8 and f_{GBW} are the same as those in FIG. 8A. In the amplifier 1, since the open-loop gain curve G0 of the operational amplifiers 11 and 12 is changed according to the set gain, the bandwidth f_{BW(const)} is determined to be a constant value at the intersections with the DC closed-loop gain at each set gain G1 to G8. Thus, the bandwidth f_{BW} at each set gain is equal to the constant bandwidth f_{BW(const)}, and becomes a stable constant bandwidth even when the set gain is high or low. Thus, according to the amplifier 1, a stable response of the amplification stage can be obtained regardless of the set gain, and the deviation in equivalent gain of the chopper amplifier from the design value also becomes constant.

Next, FIG. 8C will be described. In FIG. 8C, the horizontal axis indicates set closed-loop gain (referred to as “SG” in the figure) of the amplification stage, and the vertical axis indicates effective chopper amplifier gain (referred to as “EG” in the figure). Lines L0, L1, and L2 indicate an ideal straight line L0, characteristics of the present embodiment, and characteristics of the related art, respectively. The ideal straight line L0 is a straight line having a slope of 1, indicated by a dotted line. According to the dashed line L2 indicating the characteristics of the related art, the related art (dashed line L2) has a characteristic of approaching the ideal straight line L0 when the set gain is low, while deviating from the ideal straight line L0 as the set gain increases. On the other hand, according to the solid line L1 indicating the characteristics of the present embodiment, the amplifier according to the present embodiment has a characteristic of deviating toward the lower side from the ideal straight line L0 at any gain, and always having a constant ratio with respect to the ideal straight line L0.

Next, FIG. 8D will be described. FIG. 8D is a graph in which each line in FIG. 8C is normalized by an ideal straight line. The content indicated by lines L0, L1, and L2 illustrated in FIG. 8D is the same as in FIG. 8C. In FIG. 8D, the horizontal axis indicates set closed-loop gain (referred to as “SG” in the figure) of the amplification stage, and the vertical axis indicates normalized effective chopper amplifier gain (ratio of effective gain to set gain) (referred to as “EG/SG” in the figure) by the ideal straight line L0. It is obvious that the ideal straight line L0 is always 1. As described above, in the related art (see FIG. 8C), the deviation from the ideal straight line L0 increases as the set gain increases. In contrast, in the amplifier according to the present embodiment, while the ratio deviates toward the lower side from the ideal straight line at a ratio α at any gain, the ratio with respect to the ideal straight line is always constant (see solid line L1). According to the amplifier of the present embodiment, by setting the set gain in anticipation of this ratio α of deviation in advance, it becomes easy to obtain a desired effective gain in any gain setting.

Accordingly, according to the amplifier 1, the gain bandwidth product GBW of the operational amplifiers 11 and 12 is controlled by the capacitor bank circuit 118 so that the bandwidth BW becomes constant in accordance with the set closed-loop gain G, and the Miller compensation capacitance value is optimized. Thus, an effective chopper amplifier gain caused by gain error due to insufficient settling time can be stably obtained.

### Second Embodiment

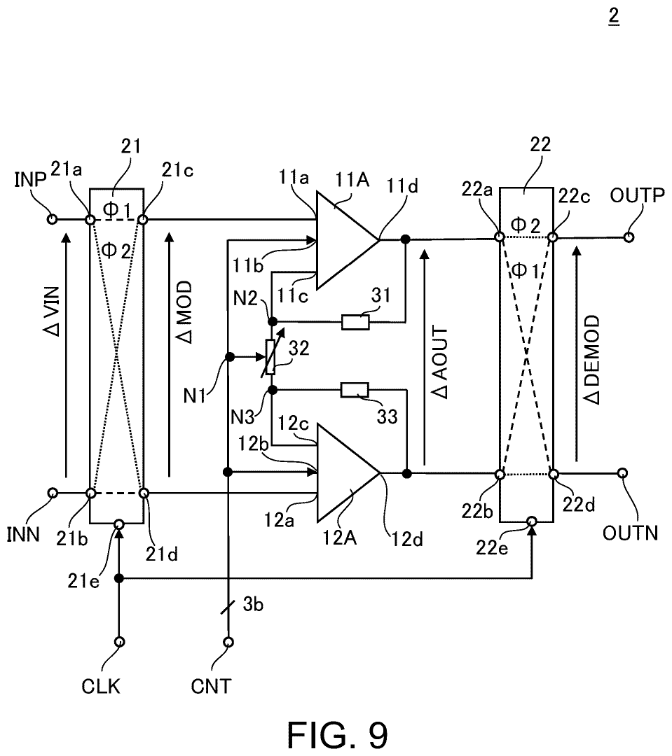

FIG. 9 is a circuit diagram schematically illustrating a configuration of an amplifier 2 which is an example of an amplifier according to a second embodiment of the present invention.

While the amplifier 2 differs from the amplifier 1 in that the amplifier 2 includes operational amplifiers 11A and 12A instead of the operational amplifiers 11 and 12, respectively, the amplifier 2 and the amplifier 1 do not substantially differ in other aspects. Thus, in the description of the present embodiment, components that do not substantially differ from those of the amplifier 1 are assigned the same reference numerals and their description is omitted.

The amplifier 2 includes the input terminals INP and INN, the chopper circuit 21, the operational amplifiers 11A and 12A, the resistors 31 and 33, the variable resistor 32, the chopper circuit 22, the clock terminal CLK, the control terminal CNT, and the output terminals OUTP and OUTN. Next, the operational amplifiers 11A and 12A will be described. The operational amplifier 12A has a configuration that does not substantially differ from that of the operational amplifier 11A. Thus, the description of the operational amplifier 11A may be substituted for the description of the operational amplifier 12A by replacing the reference numerals in the description of the operational amplifier 11A.

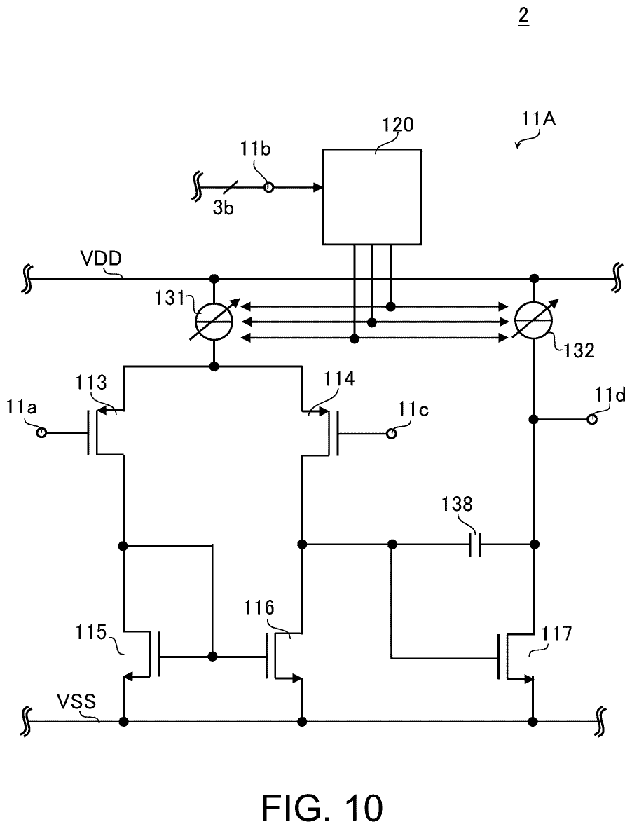

FIG. 10 is a circuit diagram illustrating a configuration example of the operational amplifier 11A in the amplifier 2.

The operational amplifier 11A differs from the operational amplifier 11 (see FIG. 4) in that the operational amplifier 11A includes a capacitive element 138 having a predetermined fixed capacitance value, instead of the capacitor bank circuit 118 in which the capacitance value between the first port 118a and the second port 118b is variable, and in that the operational amplifier 11A includes current source circuits 131 and 132 in which a current value is variable based on a control signal, instead of the current sources 111 and 112 in which the current value is a predetermined fixed value. However, the operational amplifier 11A and the operational amplifier 11 do not substantially differ in other aspects. Thus, in the description of the operational amplifier 11A, components corresponding to those of the operational amplifier 11 are assigned the same reference numerals, and repeated descriptions will be omitted.

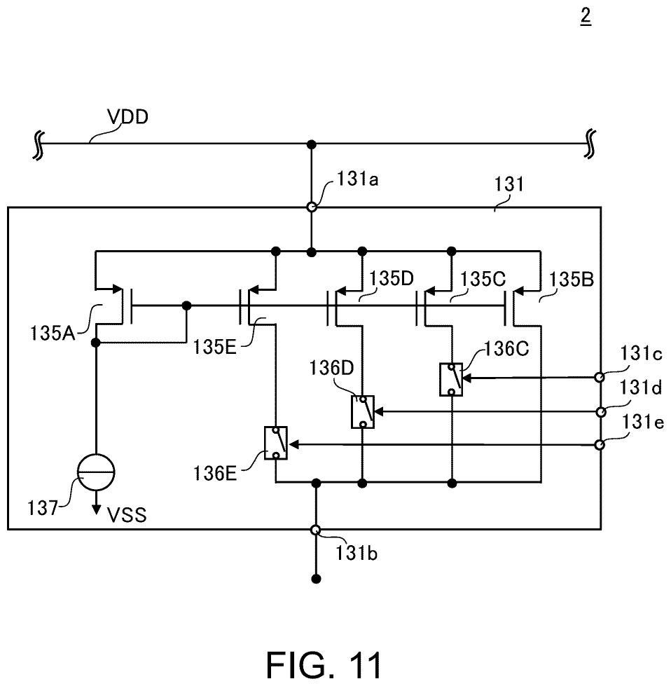

FIG. 11 is a circuit diagram illustrating a configuration example of the current source circuit 131.

The current source circuit 131 includes a first port 131a, a second port 131b, three control ports 131c, 131d, and 131e, PMOS transistors 135A to 135E, switch circuits 136C, 136D, and 136E, and a current source 137 including a first port connected to the drain of the PMOS transistor 135A and a second port connected to the power line VSS. The first port 131a and the second port 131b of the current source circuit 131 are respectively connected in the same manner as the first port and the second port of the current source 111. That is, the first port 131a is connected to the power line VDD, and the second port 131b is connected to the source of the PMOS transistor 113 and the source of the PMOS transistor 114.

The PMOS transistors 135A to 135E constitute a current mirror circuit, and are configured so that a current sunk from the current source 137, that is, a drain current of the PMOS transistor 135A, is copied and flown to the drains of the PMOS transistors 135B to 135E. The PMOS transistors 135C, 135D, and 135E are connected in series with the switch circuits 136C, 136D, and 136E, respectively. The PMOS transistor 135B, the PMOS transistor 135C and the switch circuit 136C connected in series, the PMOS transistor 135D and the switch circuit 136D connected in series, and the PMOS transistor 135E and the switch circuit 136E connected in series, are respectively connected in parallel between the first port 131a and the second port 131b.

Control ports of the switch circuits 136C, 136D, and 136E are connected to the control ports 131c, 131d, and 131e, respectively. In response to a signal supplied from the control ports 131c, 131d, and 131e, the switch circuits 136C, 136D, and 136E are controlled to be in an open state (off state) with both ends open or in a closed state (on state) with both ends short-circuited.

The current source circuit 132 has a configuration that does not substantially differ from that of the current source circuit 131. Thus, the description of the current source circuit 131 may be substituted for the description of the current source circuit 132 by replacing the reference numerals in the description of the current source circuit 131.

Next, a function of the amplifier according to the present embodiment will be described using the amplifier 2 as an example. The amplifier 2 is capable of switching a gain bandwidth of the operational amplifiers 11A and 12A by switching a current value of the current source circuits 131 and 132.

For example, the control signal is 3 bits. Here, it is assumed that the current value is set to I0 in the case where the control signal corresponding to the minimum closed-loop gain G8 is 0b000, and the current value is set to I0+I1+I2+I3 in the case where the control signal corresponding to the maximum closed-loop gain G1 is 0b111. When a mirror compensation capacitance value by the capacitive element 138 of the operational amplifiers 11A and 12A is C0, the gain bandwidth products GBW respectively corresponding to the maximum closed-loop gain G1 and the minimum closed-loop gain G8 can be expressed as follows, with K as a proportional constant:

$$GBW {( G 1 )}^{′} = K √ ( I 0 + I 1 + I 2 + I 3 ) / C 0 \qquad ( 9 )$$

$$GBW {( G 8 )}^{′} = K √ ( I 0 ) / C 0 \qquad ( 10 )$$

Here, according to the relationships in equations (4) to (5) and equations (9) to (10), it is sufficient to satisfy the relationship BW(G1)=BW(G8) in order to obtain equal bandwidth BW for the maximum closed-loop gain G1 and the minimum closed-loop gain G8, and it is sufficient to determine a constant so as to satisfy the following relationship:

$$G 21 / \sum G 2 x = √ ( \sum Ix / I 0 ) \qquad ( 11 )$$

For intermediate closed-loop gain setting, it is sufficient to determine a constant so as to satisfy similar relationships.

Accordingly, according to the amplifier 2, the gain bandwidth product GBW of the operational amplifiers 11A and 12A is controlled by the current source circuits 131 and 132 of the operational amplifiers 11A and 12A so that the bandwidth BW becomes constant in accordance with the set closed-loop gain G, and the transconductance Gm of the operational amplifiers 11A and 12A is optimized. Thus, an effective chopper amplifier gain caused by gain error due to insufficient settling time can be stably obtained.

According to the present invention, since the effective gain reduction rate due to insufficient settling time does not vary depending on the closed-loop gain setting of the amplification stage, the effective chopper amplifier gain can be stably obtained with respect to the closed-loop gain setting. Hence, the convenience of the amplifier can be improved.

The present invention is not limited to the above-described embodiments as they are, and may be implemented in various forms in addition to the above-described examples in the implementation stage. Various omissions, additions, substitutions, or modifications can be made within the scope of the invention. For example, the capacitor bank circuit 118 which is switched and controlled may be a so-called lead compensation capacitor provided in parallel with the resistors 31 and 33 which are feedback resistors, instead of the so-called Miller compensation capacitor. A capacitive element which is switched and controlled may be provided with a resistive element in series therewith for frequency zero point placement compensation. For the capacitive element, various capacitive elements, such as a metal-oxide-semiconductor (MOS) capacitor, a metal-insulator-metal (MIM) capacitor, and a metal-oxide-metal (MOM) capacitor, may be used.

The configuration of the operational amplifier is exemplified by a two-stage amplifier of N-channel input type and single-ended type. However, the operational amplifier may have a complementary configuration of P-channel input type instead of N-channel input type, or may be of a fully differential type instead of single-ended type. Furthermore, the operational amplifier is not limited to having two amplification stages, but may be a multi-stage amplifier consisting of three or more amplification stages, or may include a cascode amplifier configuration in any of the amplification stages.

In the above-described embodiments, a configuration example is described in which the resistance value of the variable resistor 32 is switchable for setting closed-loop gain. However, a configuration may be adopted in which the resistance value of the resistor 31 or the resistor 33 is switchable. A configuration example is described in which the variable resistor 32 can be controlled by switching the resistance value between two terminals. However, a midpoint terminal for common mode potential setting may further be provided.

The amplifier according to the present embodiment may include another amplification stage between either the chopper circuit 21 or the chopper circuit 22 and the amplification stage, or may further include a DC cut filter such as a high-pass filter capable of blocking a DC component included in a signal. The control signal supplied from the control terminal CNT may be preset in an inspection process before shipment, or may be dynamically automatically controlled. Furthermore, to set an appropriate delay time, a delay element or a delay circuit may be provided between the chopper circuits 21, 22 and the clock terminal CLK.

These embodiments and their modifications are included in the scope or essence of the invention, as well as within the scope of the invention described in the claims and its equivalents.

What is claimed is:

1. An amplifier comprising:
a first input terminal and a second input terminal;
a first chopper circuit, including a first input port connected to the first input terminal, a second input port connected to the second input terminal, a control port receiving a clock signal as a switching signal, a first output port, and a second output port, the first chopper circuit being capable of switching, based on the switching signal, between a first connection state in which the first input port is connected to the first output port and the second input port is connected to the second output port, and a second connection state in which the first input port is connected to the second output port and the second input port is connected to the first output port;
a first resistor;
a second resistor, including at least one control port and capable of switching a resistance value based on a control signal applied to the control port;
a third resistor;
a first operational amplifier, including a first input port connected to the first output port of the first chopper circuit, a second input port connected to one end of the first resistor and one end of the second resistor, an output port connected to an other end of the first resistor, and a control port receiving the control signal;
a second operational amplifier, including a first input port connected to the second output port of the first chopper circuit, a second input port connected to one end of the third resistor and an other end of the second resistor, an output port connected to an other end of the third resistor, and a control port receiving the control signal;
a second chopper circuit, including a first input port connected to the output port of the first operational amplifier, a second input port connected to the output port of the second operational amplifier, a control port receiving the clock signal as the switching signal, a first output port, and a second output port, the second chopper circuit being capable of switching, based on the switching signal, between a first connection state in which the first input port is connected to the first output port and the second input port is connected to the second output port, and a second connection state in which the first input port is connected to the second output port and the second input port is connected to the first output port; and
a first output terminal connected to the first output port of the second chopper circuit and a second output terminal connected to the second output port of the second chopper circuit,
the first operational amplifier and the second operational amplifier being configured to switch a gain bandwidth product of the first operational amplifier and the second operational amplifier based on the control signal.

2. The amplifier according to claim 1, wherein
at least one of the first operational amplifier and the second operational amplifier includes a capacitor bank circuit capable of switching capacitance value based on the control signal received from the control port.

3. The amplifier according to claim 1, wherein
at least one of the first operational amplifier and the second operational amplifier includes a current source capable of switching a drive current value of the first operational amplifier and the second operational amplifier based on the control signal received from the control port.
